(19) United States
(12) Patent Application Publication
(10) Pub. No.: US 2006/0093795 A1
(43) Pub. Date: May 4, 2006

(54) Polymeric substrate having a desiccant layer

(75) Inventors: Jin-Shan Wang, Pittsford, NY (US); Kathleen M. Vaeth, Rochester, NY (US); Terrence R. O'Toole, Webster, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/981,167

(22) Filed: Nov. 4, 2004

(51) Int. Cl. B32B 3/00

(52) U.S. Cl. 428/195.1

(57) ABSTRACT

A polymeric substrate for a moisture-sensitive electronic device includes a polymeric support having a top and bottom surface, and a desiccant layer disposed over at least a portion of the top or bottom surface of the polymeric support, or both.

### CROSS REFERENCE TO RELATED APPLICATIONS

Reference is made to commonly assigned U.S. patent application Ser. No. ______ filed ______ by Jin-Shan Wang, et al., entitled “Flexible Support for Electronic Device”; commonly assigned U.S. patent application Ser. No. ______ filed Oct. 22, 2004 by Amalkumar P. Ghosh, et al., entitled “Desiccant Film in Top-Emitting OLED”; commonly assigned U.S. patent application Ser. No. 10/946,425 filed Sep. 21, 2004 by Jin-Shan Wang, et al., entitled “Desiccant Having a Reactive Salt”; and commonly assigned U.S. patent application Ser. No. 10/946,543 filed Sep. 21, 2004 by Jin-Shan Wang, et al., entitled “Lewis Acid Organometallic Desiccant”; the disclosures of which are herein incorporated by reference.

### FIELD OF THE INVENTION

The present invention relates to polymeric substrates for moisture-sensitive electronic devices.

### BACKGROUND OF THE INVENTION

It is desirable to use a polymeric substrate for various electronic devices in order to make them flexible. Such devices include organic light-emitting diode (OLED) displays, LCD displays, photovoltaics, and sensors. However, many such devices are sensitive to moisture and polymeric substrates typically have high Water permeability. To address this problem, it has been proposed to coat moisture barrier layers over the polymeric substrates, for example, for use with flexible OLEDs. However, it is still very difficult to avoid defects that permit moisture into the electronic device. There is a continuing need to improve the moisture protection of electronic devices on polymeric substrates.

### SUMMARY OF THE INVENTION

It is therefore an object of the present invention to provide an effective way of preventing moisture from degrading the performance of an electronic device on a polymeric substrate.

This object is achieved by a polymeric substrate for a moisture-sensitive electronic device comprising:

a) a polymeric support having a top and bottom surface; and

b) a desiccant layer disposed over at least a portion of the top or bottom surface of the polymeric support, or both.

### ADVANTAGES

The invention provides an electronic device on a polymeric substrate that is better protected from moisture, thereby achieving longer lifetime and excellent device performance. The invention further provides a way for protecting a flexible OLED device without negatively impacting the light transmission characteristics of the polymeric support.

### BRIEF DESCRIPTION OF THE DRAWINGS

FIG. 1 is a cross-sectional view of an OLED device;

FIG. 2A is a cross-sectional view of a polymeric substrate of this invention;

FIG. 2B is a cross-sectional view of another polymeric substrate of this invention;

FIG. 2C is a cross-sectional view of yet another polymeric substrate of this invention;

FIG. 2D is a cross-sectional view of still another polymeric substrate of this invention;

FIG. 3 is a cross-sectional view of another polymeric substrate of this invention;

FIG. 4 is a cross-sectional view of another polymeric substrate of this invention;

FIG. 5 is a plan view of an OLED having first electrode and contact pads provided over a polymeric substrate of this invention;

FIG. 6 shows the OLED of FIG. 5 after deposition of a patterned insulator layer;

FIG. 7A is a plan view of the OLED from FIG. 6 after deposition of the organic EL media and second electrode;

FIG. 7B is a cross-sectional view of the OLED device of FIG. 7A taken along lines 7B-B;

FIG. 8 is a cross-sectional view of the OLED device of FIG. 7 with various other functional layers for encapsulation;

FIG. 9A is a plan view of a polymeric substrate of this invention with a patterned desiccant layer;

FIG. 9B is a cross-sectional view of the polymeric substrate of FIG. 9 taken along lines 9A-A;

FIG. 10 is a cross-sectional view of an OLED device using the polymeric substrate of FIG. 9A; and

FIG. 11 is a cross-sectional view of a polymeric substrate of this invention with multiple layers of patterned desiccant.

### DETAILED DESCRIPTION OF THE INVENTION

The present invention can be used with any electronic device having a polymeric support and requiring moisture protection. In particular, this invention is suitable for flexible OLED devices provided on a polymeric support. The features of a typical OLED device will now be discussed.

General OLED Device Architecture

The present invention can be employed in most OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

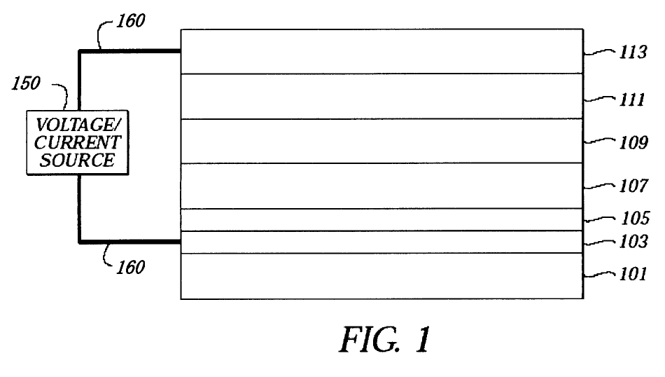

There are numerous configurations of the organic layers wherein the present invention can be successfully practiced. A schematic of a pixel area of the device, not to scale, is shown in FIG. 1. It includes a substrate 101, an anode 103, a hole-injecting layer 105, a hole-transporting layer 107, a light-emitting layer 109, an electron-transporting layer 111, and a cathode 113. The substrate of this invention includes a polymeric support. These layers are described in more detail below. Note that the cathode can alternatively be located adjacent to the substrate. The organic layers between the anode and cathode are conveniently referred to as the organic EL element or organic EL media. The total combined thickness of the organic layers is preferably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode and electrons are injected into the organic EL element at the anode. Enhanced device stability can sometimes be achieved when the OLED is operated in an alternating current (AC) mode where, for some time period in the cycle, the potential bias is reversed and no current flows. An example of an AC driven OLED is described in U.S. Pat. No. 5,552,678.

Anode

When EL emission is viewed through anode 103, the anode should be transparent or substantially transparent to the emission of interest. Common transparent anode materials used in this invention are indium-tin oxide (ITO), indium-zinc oxide (IZO), and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode electrode, the transmissive characteristics of anode are immaterial and any conductive material can be used, transparent, opaque, or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well known photolithographic processes. Optionally, anodes can be polished prior to application of other layers to reduce surface roughness so as to reduce shorts or enhance reflectivity.

Hole-Injecting Layer (HIL)

It is often useful to provide a hole-injecting layer 105 between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. Nos. 6,127,004, 6,208,075, and 6,208,077, some aromatic amines, for example, m-MTDATA (4,4′,4″-tris[(3-methylphenyl)-phenylamino]triphenylamine), and inorganic oxides including vanadium oxide (VOx), molybdenum oxide (MoOx), and nickel oxide (NiOx). Alternative hole-injecting materials reportedly useful in organic EL devices are described in EP 0 891 121 A1 and EP 1 029 909 A1.

Hole-Transporting Layer (HTL)

The hole-transporting layer 107 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel, et al. U.S. Pat. No. 3,180,730. Other suitable triarylamines substituted with one or more vinyl radicals and/or comprising at least one active hydrogen containing group are disclosed by Brantley, et al. U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:
1,1-Bis(4-di-p-tolylaminophenyl)cyclohexane;
1,1-Bis(4-di-p-tolylaminophenyl)-4-phenylcyclohexane;
N,N,N′,N′-tetraphenyl-4,4′″-diamino-1,1′:4′, 1″:4″, 1′″-quaterphenyl;
Bis(4-dimethylamino-2-methylphenyl)phenylmethane;
1,4-bis[2-[4-[N,N-di(p-toly)amino]phenyl]vinyl]benzene (BDTAPVB);
N,N,N′,N′-Tetra-p-tolyl-4,4′-diaminobiphenyl;
N,N,N′,N′-Tetraphenyl-4,4′-diaminobiphenyl;
N,N,N′,N′-tetra-1-naphthyl-4,4′-diaminobiphenyl;
N,N,N′,N′-tetra-2-naphthyl-4,4′-diaminobiphenyl;
N-Phenylcarbazole;
4,4′-Bis[N-(1-naphthyl)-N-phenylamino]biphenyl (NPB);
4,4′-Bis[N-(1-naphthyl)-N-(2-naphthyl)amino]biphenyl (TNB);
4,4′-Bis[N-(1-naphthyl)-N-phenylamino]ₚ-terphenyl;
4,4′-Bis[N-(2-naphthyl)-N-phenylamino]biphenyl;
4,4′-Bis[N-(3-acenaphthenyl)-N-phenylamino]biphenyl;
1,5-Bis[N-(1-naphthyl)-N-phenylamino]naphthalene;
4,4′-Bis[N-(9-anthryl)-N-phenylamino]biphenyl;
4,4′-Bis[N-(1-anthryl)-N-phenylamino]-p-terphenyl;
4,4′-Bis[N-(2-phenanthryl)-N-phenylamino]biphenyl;
4,4′-Bis[N-(8-fluoranthenyl)-N-phenylamino]biphenyl;
4,4′-Bis[N-(2-pyrenyl)-N-phenylamino]biphenyl;
4,4′-Bis[N-(2-naphthacenyl)-N-phenylamino]biphenyl;
4,4′-Bis[N-(2-perylenyl)-N-phenylamino]biphenyl;
4,4′-Bis[N-(1-coronenyl)-N-phenylamino]biphenyl;
2,6-Bis(di-p-tolylamino)naphthalene;
2,6-Bis[di-(1-naphthyl)amino]naphthalene;
2,6-Bis[N-(1-naphthyl)-N-(2-naphthyl)amino]naphthalene;
N,N,N′,N′-Tetra(2-naphthyl)-4,4″-diamino-p-terphenyl;
4,4′-Bis {N-phenyl-N-[4-(1-naphthyl)-phenyl]amino}biphenyl;
2,6-Bis[N,N-di(2-naphthyl)amino]fluorene;
4,4′,4″-tris[(3-methylphenyl)phenylamino]triphenylamine (MTDATA); and
4,4′-Bis[N-(3-methylphenyl)-N-phenylamino]biphenyl (TPD).

Another class of useful hole-transporting materials includes polycyclic aromatic compounds as described in EP 1 009 041. Some hole-injecting materials described in EP 0 891 121 A1 and EP 1 029 909 A1 can also make useful hole-transporting materials. In addition, polymeric hole-transporting materials can be used including poly(N-vinylcarbazole) (PVK), polythiophenes, polypyrrole, polyaniline, and copolymers including poly(3,4-ethylenedioxythio-phene)/poly(4-styrenesulfonate), also called PEDOT/PSS.

Light-Emitting Layer (LEL)

As more fully described in U.S. Pat. Nos. 4,769,292 and 5,935,721, each of the light-emitting layers (LEL) of the organic EL element include a luminescent fluorescent or phosphorescent material where electroluminescence is produced as a result of electron-hole pair recombination in this region. The light-emitting layer can be comprised of a single material, but more commonly contains a host material doped with a guest emitting material, or materials where light emission comes primarily from the emitting materials and can be of any color. This guest emitting material is often referred to as a light-emitting dopant. The host materials in the light-emitting layer can be an electron-transporting material, as defined below, a hole-transporting material, as defined above, or another material or combination of materials that support hole-electron recombination. The emitting material is typically chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small nonpolymeric molecules or polymeric materials including polyfluorenes and polyvinylarylenes, e.g., poly(p-phenylenevinylene), PPV. In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential, which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters (including materials that emit from a triplet excited state, i.e., so-called “triplet emitters”) it is also important that the host triplet energy level of the host be high enough to enable energy transfer from host to emitting material.

Host and emitting materials known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, 6,020,078, 6,475,648, 6,534,199, 6,661,023, U.S. Patent Application Publications 2002/0127427 A1, 2003/0198829 A1, 2003/0203234 A1, 2003/0224202 A1, and 2004/0001969 A1, the disclosures of which are herein incorporated by reference.

Metal complexes of 8-hydroxyquinoline (oxine) and similar derivatives constitute one class of useful host compounds capable of supporting electroluminescence. Illustrative of useful chelated oxinoid compounds are the following:
CO-1: Aluminum trisoxine [alias, tris(8-quinolinolato)aluminum(III)];
CO-2: Magnesium bisoxine [alias, bis(8-quinolinolato)magnesium(II)];
CO-3: Bis[benzo{f}-8-quinolinolato]zinc (II);
CO-4: Bis(2-methyl-8-quinolinolato)aluminum(III)-μ-oxo-bis(2-methyl-8-quinolinolato) aluminum(III);
CO-5: Indium trisoxine [alias, tris(8-quinolinolato)indium];
CO-6: Aluminum tris(5-methyloxine) [alias, tris(5-methyl-8-quinolinolato) aluminum(III)];
CO-7: Lithium oxine [alias, (8-quinolinolato)lithium(I)];
CO-8: Gallium oxine [alias, tris(8-quinolinolato)gallium(III)]; and
CO-9: Zirconium oxine [alias, tetra(8-quinolinolato)zirconium(IV)].

Another class of useful host materials includes derivatives of anthracene, such as those described in WO 2004018587, U.S. Pat. Nos. 5,935,721, 5,972,247, 6,465,115, 6,534,199, 6,713,192, U.S. Patent Application Publications 2002/0048687 A1, and 2003/0072966 A1, the disclosures of which are herein incorporated by reference. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2, 2′, 2″-(1,3,5-phenylene)tris[1-phenyl-1H-benzimidazole].

Desirable host materials are capable of forming a continuous film. The light-emitting layer can contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, derivatives of distryrylbenzene and distyrylbiphenyl, and carbostyryl compounds. Among derivatives of distyrylbenzene, particularly useful are those substituted with diarylamino groups, informally known as distyrylamines.

Suitable host materials for phosphorescent emitters (including materials that emit from a triplet excited state, i.e., so-called “triplet emitters”) should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655 A2, WO 01/39234 A2, WO 01/93642 A1, WO 02/074015 A2, WO 02/15645 A1, and U.S. Patent Application Publication 2002/0117662 A1, the disclosure of which is herein incorporated by reference. Suitable hosts include certain aryl amines, triazoles, indoles, and carbazole compounds. Examples of desirable hosts are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

Examples of useful phosphorescent materials that can be used in light-emitting layers of this invention include, but are not limited to, those described in WO 00/57676, WO 00/70655, WO 01/41512 A1, WO 02/15645 A1, WO 01/93642 A1, WO 01/39234 A2, WO 02/071813 A1, WO 02/074015 A2, U.S. Pat. Nos. 6,451,455, 6,458,475, 6,573,651, 6,413,656, 6,515,298, 6,451,415, 6,097,147, EP 1 239 526 A2, EP 1 238 981 A2, EP 1 244 155 A2, JP 2003059667A, JP 2003073665A, JP 2003073387A, JP 2003 073388A, U.S. Patent Application Publications 2003/0124381 A1, 2003/0059646 A1, 2003/0054198 A1, 2003/0017361 A1, 2003/0072964 A1, 2003/0068528 A1, 2002/0100906 A1, 2003/068526 A1, 2003/0068535 A1, 2003/0141809 A1, 2003/0040627 A1, 2002/0197511 A1, and 2002/0121638 A1, the disclosures of which are herein incorporated by reference.

Electron-Transporting Layer (ETL)

Preferred thin film-forming materials for use in forming the electron-transporting layer 111 of the organic EL elements of this invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Cathode

When light emission is viewed solely through the anode, the cathode 113 used in this invention can be comprised of nearly any conductive material. Desirable materials have effective film-forming properties to ensure effective contact with the underlying organic layer, promote electron injection at low voltage, and have effective stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g., ETL), which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

A metal-doped organic layer can be used as an electron-injecting layer. Such a layer contains an organic electron-transporting material and a low work-function metal (<4.0 eV). For example, Kido, et al. reported in “Bright Organic Electroluminescent Devices Having a Metal-Doped Electron-Injecting Layer”, Applied Physics Letters, 73, 2866 (1998) and disclosed in U.S. Pat. No. 6,013,384 that an OLED can be fabricated containing a low work-function metal-doped electron-injecting layer adjacent to a cathode. Suitable metals for the metal-doped organic layer include alkali metals (e.g. lithium, sodium), alkaline earth metals (e.g. barium, magnesium, calcium), or metals from the lanthanide group (e.g. lanthanum, neodymium, lutetium), or combinations thereof. The concentration of the low work-function metal in the metal-doped organic layer is in the range of from 0.1% to 30% by volume. Preferably, the concentration of the low work-function metal in the metal-doped organic layer is in the range of from 0.2% to 10% by volume. Preferably, the low work-function metal is provided in a mole ratio in a range of from 1:1 with the organic electron transporting material.

When light emission is viewed through the cathode, the cathode should be transparent or nearly transparent. For such applications, metals should be thin or one should use transparent conductive oxides, or include these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, JP 3,234,963, and EP 1 076 368. Cathode materials are typically deposited by evaporation, sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

Other Common Organic Layers and Device Architecture

In some instances, layers 109 and 111 can optionally be collapsed into a single layer that serves the function of supporting both light emission and electron transportation. It also known in the art that emitting dopants can be added to the hole-transporting layer, which can serve as a host. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. Nos. 5,683,823, 5,503,910, 5,405,709, 5,283,132, 6,627,333, U.S. Patent Application Publications 2002/0186214 A1, 2002/0025419 A1, and 2004/0009367 A1, the disclosures of which are herein incorporated by reference.

Additional layers such as exciton, electron and hole-blocking layers as taught in the art can be employed in devices of this invention. Hole-blocking layers are commonly used to improve efficiency of phosphorescent emitter devices, for example, as in WO 00/70655A2, WO 01/93642A1, U.S. Patent Application Publications 2003/0068528 A1, 2003/0175553 A1, and 2002/0015859 A1, the disclosures of which are herein incorporated by reference.

This invention can be used in so-called stacked device architecture, for example, as taught in U.S. Pat. Nos. 5,703,436, 6,337,492, 6,717,358, and U.S. Patent Application Publication 2003/0170491 A1, the disclosure of which is herein incorporated by reference.

Deposition of Organic Layers

The organic materials mentioned above are suitably deposited through a vapor phase method such as sublimation, but can be deposited from a fluid, for example, from a solvent with an optional binder to improve film formation. If the material is a polymer, solvent deposition is useful, but other methods can be used, such as sputtering, chemical vapor deposition, or thermal transfer from a donor sheet. The material to be deposited by sublimation can be vaporized from a sublimation “boat” often comprised of a tantalum material, e.g., as described in U.S. Pat. No. 6,237,529, or can be first coated onto a donor sheet and then sublimed in closer proximity to the substrate. Layers with a mixture of materials can use separate sublimation boats or the materials can be premixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551, 5,851,709, and 6,066,357), and inkjet method (U.S. Pat. No. 6,066,357).

Optical Optimization

OLED devices of this invention can employ various well known optical effects in order to enhance its properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color conversion filters in functional relationship with the light-emitting areas of the display. Filters, polarizers, and anti-glare or anti-reflection coatings can also be provided over a cover or as part of a cover.

The OLED device can have a microcavity structure. In one useful example, one of the metallic electrodes is essentially opaque and reflective; the other one is reflective and semitransparent. The reflective electrode is preferably selected from Au, Ag, Mg, Ca, or alloys thereof. Because of the presence of the two reflecting metal electrodes, the device has a microcavity structure. The strong optical interference in this structure results in a resonance condition. Emission near the resonance wavelength is enhanced and emission away from the resonance wavelength is depressed. The optical path length can be tuned by selecting the thickness of the organic layers or by placing a transparent optical spacer between the electrodes. For example, an OLED device of this invention can have ITO spacer layer placed between a reflective anode and the organic EL media, with a semitransparent cathode over the organic EL media.

Encapsulation

As stated, OLED devices are sensitive to moisture or oxygen, or both, so they are commonly sealed in an inert atmosphere such as nitrogen or argon. In sealing an OLED device in an inert environment, a protective cover can be attached using an organic adhesive, a metal solder, or a low melting temperature glass. Because polymeric support materials are typically sensitive to heat, organic adhesives are preferred. In addition, if the device is flexible, the cover should also flex. A desiccant can be provided within the sealed space. Various desiccants can be used including, for example, alkali and alkaline metals, alumina, bauxite, calcium sulfate, clays, silica gel, zeolites, alkaline metal oxides, alkaline earth metal oxides, sulfates, or metal halides and perchlorates. Desiccating films having a host and a molecularly dispersed desiccant material can also be used, such films are discussed below. In addition, the desiccant can be used in combination with barrier layers such as SiOx, Teflon, and alternating inorganic/polymeric layers as known in the art. Barrier layers can be provided over the OLED, between the OLED and a flexible support, or both.

Some nonlimiting examples of inorganic barrier layer materials include metal oxides such as silicon oxides and aluminum oxides, and metal nitrides such as silicon nitride. Metal oxynitrides are also useful. Suitable examples of inorganic barrier layer materials include aluminum oxide, silicon dioxide, silicon nitride, silicon oxynitride, and diamond-like carbon. In some circumstances it is useful if the inorganic barrier layer material can be electronically conductive, such as a conductive metal oxide, a metal or metal alloy. In this case, the conductive inorganic barrier layer can carry current to one or more device electrodes, serve as the electrode, or provide a way for discharging static electricity. Metals such as Al, Ag, Au, Mo, Cr, Pd, or Cu, or alloys containing these metals can be useful inorganic barrier layers. Multiple layers of metal can be used to fabricate a conductive inorganic barrier layer. Where unwanted shorting can occur, conductive barrier layers should not be used, or they should be patterned, e.g., with a shadow mask, such that they do not cause shorting. The inorganic barrier layer is typically provided in a thickness of ten to several hundreds of nanometers.

Useful techniques of forming layers of inorganic barrier layer material from a vapor phase include, but are not limited to, thermal physical vapor deposition, sputter deposition, electron beam deposition, chemical vapor deposition (CVD), plasma-enhanced chemical vapor deposition, laser-induced chemical vapor deposition, and atomic layer deposition (ALD). CVD and ALD are particularly useful. In some instances, said materials can be deposited from a solution or another fluidized matrix, e.g., from a super critical solution of CO₂. Care should be taken to choose a solvent or fluid matrix does not negatively affect the performance of the device. Patterning of said materials can be achieved through many ways including, but not limited to, photolithography, lift-off techniques, laser ablation, and more preferably, through shadow mask technology.

The organic barrier layer material can be monomeric or polymeric, and can be deposited using vapor deposition or from solution. If cast from solution, it is important that the deposition solution does not negatively affect the OLED device.

Conveniently, the organic barrier layer is made of a polymeric materials such as parylene materials, which can be deposited from a vapor phase to provide a polymer layer having excellent adhesion to, and step coverage over, topological features of the OLED devices, including defects such as particulate defects. The organic barrier layer is typically formed in a thickness range of from 0.01 to 5 micrometer. However, by their very nature, the organic materials in the organic barrier layer exhibit more moisture permeability than a layer formed of an inorganic dielectric material or a layer formed of a metal. Thus, it is often desirable to encase the organic barrier layer with an inorganic material.

### EMBODIMENTS

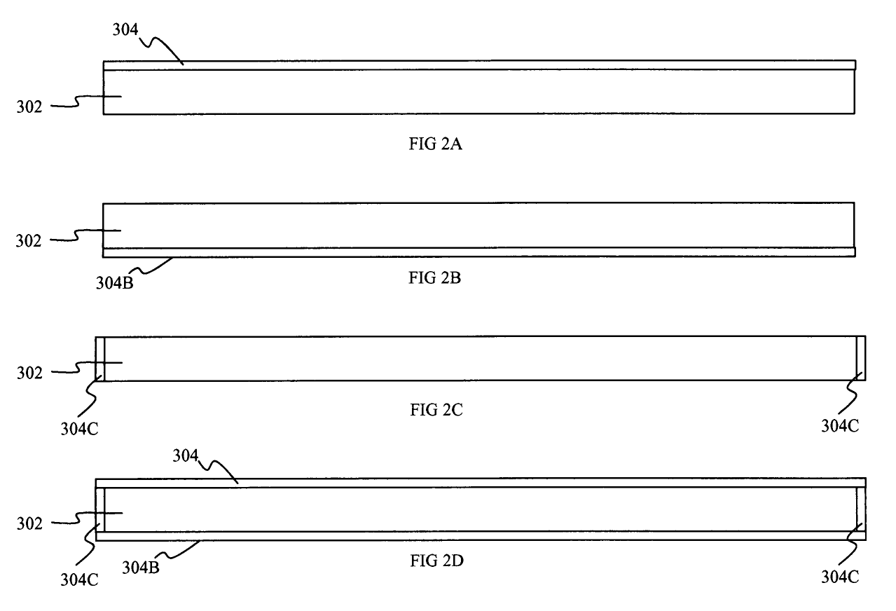

Turning now to FIG. 2A, a cross-sectional view of one embodiment of this invention is shown. Here, where the desiccant layer 304 is provided as a layer over a first surface of a polymeric support 302 that is to be used as a substrate for an electronic device such as an OLED. The polymeric support 302 can be flexible. Some nonlimiting examples of useful polymeric support materials include polyolefins, for example, polyethylene and polypropylene; polyesters; polyarylates, polyacrylates, polyethyleneterephthalate; polyethylenenaphthalate; polystyrene; polyamides; polyimides; polyethersulfonate, and polyorganosilicones, as well as other transparent polymers and copolymers including other high T_{g} polymers.

As shown in FIG. 2B and FIG. 2C, desiccant layer 304 can be provided on other surfaces of the support, alone or in combination. Desiccant layer 304B is provided on a second surface that is opposite the first surface (i.e., opposite the side where the electronic device is fabricated), and desiccant layer 304C is provided on the edges of the polymeric support. Desiccant layers 304, 304B, and 304C can be the same or different, but are conveniently the same. If light is transmitted through the support, the desiccant should be light transmissive. As shown in FIG. 2D, desiccant can be provided on all sides of the polymeric support 302. Although not shown, a barrier layer can be provided over desiccant layers 304, 304B, and 304C.

Various materials can be used for desiccant layer 304 (for the purposes of discussion, this includes 304B and 304C) including, for example, alkali and alkaline metals, alumina, bauxite, calcium sulfate, clays, silica gel, zeolites, alkaline metal oxides, alkaline earth metal oxides, sulfates, or metal halides and perchlorates. Preferably, desiccant layer 304 includes a metal complex selected from formulas I, IV, V, VI, and VII below. Advantageously, desiccant layer 304 is a light transmissive desiccating film having a host and a molecularly dispersed desiccant material provided within the host. A “molecularly dispersed desiccant” is a water reactive molecule or a water reactive functional group provided within an inert “host” so that such reactive molecule or group is diluted relative to a pure film of the desiccant. Molecularly dispersed desiccants are discussed in more detail below. An advantage of providing the molecularly dispersed desiccant within a host is that this reduces the formation of aggregates or particles, especially if the desiccant is a metal complex or organometallic material. One common byproduct of the reaction of water with such metal-containing materials is the formation of metal oxides that are prone to aggregate and form small particles. Such aggregates and particles can absorb or scatter light. This is undesirable when light is emitted through the desiccant.

One class of useful desiccant material includes a Lewis acid organometallic structure that, when it reacts with water, forms a carbon-hydrogen bond but does not form an alcohol. Alcohols can adversely affect the performance of an OLED device if they are permitted to diffuse into the OLED device. This class of material limits this concern. In one preferred embodiment, the Lewis acid has the structure shown in Formula (I)
R¹ₙ-M-R²ₘ (I)
wherein:

M is a metal;

R¹ is an organic substituent wherein at least one carbon is directly bonded to the metal;

R² is a silyl oxide substituent wherein the oxygen is directly bonded to the metal, or an amide substituent having a nitrogen directly bonded to the metal; and

n=1, 2, 3, or 4 and m=0, 1, 2, or 3 and are selected to fulfill the coordination requirements of M so that Formula I is neutral in charge.

Metals selected from Group IIB, IIIA, IIIB, or IVB, or first row transition metals are useful in present invention. Preferably, they are Al, Zn, Ti, Mg, or B.

When more than one R¹ substituent is used, the R¹ substituents can be the same or different from each other. Likewise, when more than one R² substituent is used, the R² substituents can be the same or different from each other.

Some useful examples of organic substituents that can be used as R¹ include alkyl, alkenyl, aryl, and heteroaryl compounds where a saturated or unsaturated carbon is bonded to the metal. These compounds can be further substituted with alkyl, alkenyl, aryl, heteroaryl, halogen, cyano, ether, ester, or tertiary amine groups, or combinations thereof. Some nonlimiting examples of R¹ methyl, ethyl, n-propyl, n-butyl, n-pentyl, n-hexyl, n-heptyl, n-octyl, i-propyl, t-butyl, cyclohexyl, tetradecyl, octadecyl, benzyl, phenyl, and pyridyl. In addition, R¹ can be part of an oligomeric or polymeric system. For example, R¹ can be a part of a polystyrene, polybutadiene, polymethacrylate, polysiloxane, or polyfluorene structure.

Silyl oxides with the following Formula II can be selected as R² for the present invention: 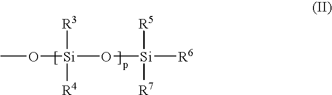
wherein R³ through R⁶ are organic substituents and p is an integer from 0 to 1000. Some organic substituents useful for R³ through R⁶ include alkyl, alkenyl, aryl, and heteroaryl compounds, which can be further substituted with alkyl, alkenyl, aryl, heteroaryl, halogen, cyano, ether, ester, or tertiary amine groups, or combinations thereof. Preferably R³ through R⁶ are alkyl or aryl groups.

Amides with the following Formula III can be selected as R² for the present invention: 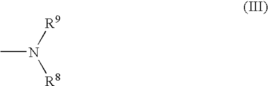
wherein R⁸ and R⁹ are organic substituents. Some organic substituents useful for R⁸ and R⁹ include alkyl, alkenyl, aryl, and heteroaryl compounds, which can be further substituted with alkyl, alkenyl, aryl, heteroaryl, halogen, cyano, ether, ester, or tertiary amine groups, or combinations thereof. R⁸ and R⁹ can be joined to form a ring system. R⁸ or R⁹ or both can be part of an oligomeric or polymeric system. For example, R⁸ or R⁹ can be a part of a polystyrene, polybutadiene, polymethacrylate, polysiloxane, or polyfluorene structure.

Although not shown in Formula I, there can be additional, non charge-bearing moieties weakly or strongly coordinated to the metal center. For example, there can be solvent molecules coordinated to the metal center in addition to R¹.

Examples of useful desiccant materials for practicing this invention include, but are not limited to, Al(C₂H₅)₃, Al(C₄H₉)₃, B(C₄H₉)₃, Zn(C₄H₉)₂, Al(t-butyl)₃, Ti(t-butyl)₄, Mg(t-butyl)₂, Al(C₄H₉)₂(N(C₆H₅)₂), Al(C₄H₉)(N(C₆H₅)₂)₂, and the structures shown below:

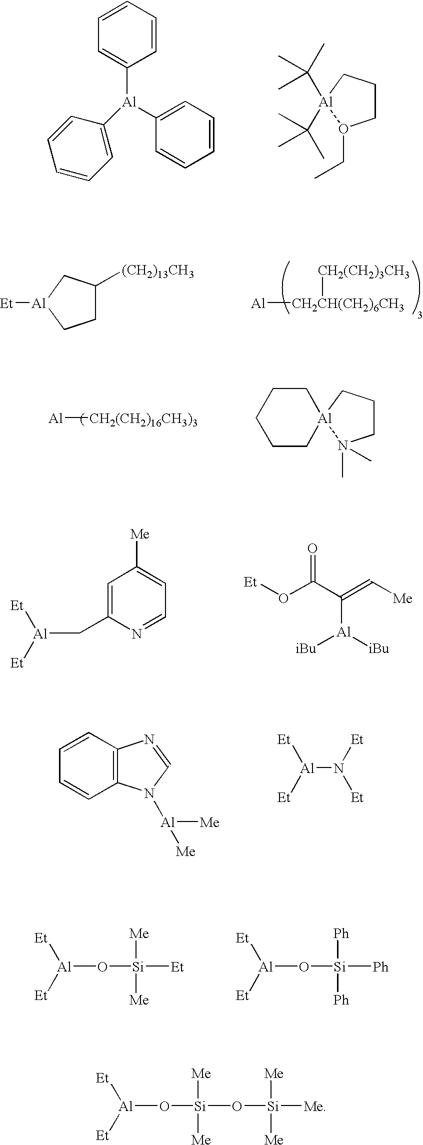

Equations 1-3 show how these moisture-absorbing materials react with water, using various examples of R¹ and R² formula I wherein M is aluminum. For example:
Al(C₄H₉)₃+3H₂O→3C₄H₁₀+Al(OH)₃ (1)
Al(C₄H₉)((OSi(CH₃)₂)₅₀C₂H₅)₂+3H₂O→C₄H₁₀+2Si(OH)(CH₃)₂)₅₀C₂H₅+Al(OH)₃ (2)
Al(C₄H₉)₂(N(C₆H₅)₂)+3H₂O→2C₄H₁₀+2NH(C₆H₅)₂+Al(OH)₃ (3).

As can be seen, R¹ of all compounds reacts with water to form a carbon-hydrogen bond. In the case of R² the reaction with water forms a silyl oxygen-hydrogen bond or a nitrogen-hydrogen bond. None of these substituents form harmful alcohol species. The reaction products are also substantially transparent to visible light. In some instances, it can be advantageous to avoid the build up gaseous byproducts. When this is desired, R¹ and R² should be selected to have 6 or more carbon atoms so that their reaction products with water have a low vapor pressure at temperatures less than 50° C.

Methods for synthesizing the Lewis acid organometallic desiccant of this invention can be found in Salt Effects in Organic and Organometallic Chemistry, VCH Publishers, Inc, New York, 1992.

Another useful moisture absorbing material of this invention includes a reactive salt of a negatively charged organometallic complex that, when it reacts with water, forms a carbon-hydrogen bond but does not form an alcohol.

In a preferred embodiment, the reactive salt has the structure shown in Formula (IV)
(A^{+b})_{c}[M(R¹)ₙ(R²)ₘ(X)ₗ]^{-q} (IV)
wherein:

A is a cation having charge b;

M is a metal;

R¹ is an organic substituent wherein at least one carbon is directly bonded to the metal;

R² is a silyl oxide wherein the oxygen is directly bonded to the metal, or an amide having a nitrogen directly bonded to the metal;

X is an anionic substituent having a pKa <7;

l=1 or 2;

n=1, 2, 3, or 4;

m=0, 1, 2, or 3;

q=is the charge of the anionic organometallic complex and is 1 or 2; and

b=q/c.

Metals selected from Group IIB, IIIA, IIIB, or IVB, or first row transition metals are useful in present invention, preferably Al, Zn, Ti, Mg, or B.

When more than one R¹ substituent is used, the R¹ substituents can be the same or different from each other. Likewise, when more than one R² or X substituent is used, the R² or X substituents can be the same or different from each other.

Some useful examples of R¹ and R² are those previously described in relation to Formula I.

The substituent X can be an inorganic anionic material such as fluoride, chloride, bromide, iodide, nitrate, sulfate, tetrafluoroborate, hexafluorophosphate, or perchlorate. Alternatively, X can be an organic anionic material including a carboxylate, a sulfonate, or a phosphonate. When X is organic, it can be part of an oligomeric or polymeric system. Some examples of organic materials suitable for X include acetate, formate, succinate, toluenesulfonate, and polystyrenesulfonate.

The cation A can be a positively charged metal ion such as an alkali, alkaline, or alkaline earth metal. Cation A can be a positively charged metal complex, for example, a complex of an alkali, alkaline, or alkaline earth metal with a crown ether, an alkylpolyamine, or the like. Alternatively, cation A can be a positively charged organic compound. Preferred positively charged organic compounds include those that contain nitrogen or phosphorous. Some examples of positively charged organic compounds suitable as cation A include tetraalkylammonium, alkylpyridinium, and tetraalkylphosphonium compounds. When cation A is a positively charged metal complex or organic compound, it can be part of an oligomeric or polymeric system such as a polyvinylpyridinium system.

Although not shown in Formula IV, there can be additional, non charge-bearing moieties weakly or strongly coordinated to the metal center. For example, there can be solvent molecules coordinated to the metal center in addition to R¹ and X.

A few nonlimiting examples of useful desiccant materials for practicing this invention include K[Al(C₂H₅)₃F], [N(CH₃)₄][Al(C₄H₉)₃Cl], [N(C₄H₉)₄][B(C₅H₅)₃F], [N-t-butylpyridinium][B(C₅H₅)₃(OC(═O)—C₅H₅)], Li₂[Zn(C₄H₉)₂Cl], and K[(i-Bu)₃Al—F—Al(i-Bu)₃].

Equation 4 shows one example of how these moisture-absorbing materials react with water
K[Al(C₂H₅)₃F]+3H₂O→3C₂H₅+Al(OH)₃+KF (4).

As can be seen, R¹ reacts with water to form a carbon-hydrogen bond. In the case of R² (not shown) the reaction with water forms a silyl oxygen-hydrogen bond or a nitrogen-hydrogen bond. None of these substituents form harmful alcohol species. The reaction products are also substantially transparent to visible light. In some instances, it can be advantageous to avoid the build up gaseous byproducts. When this is desired, R¹ and R² should be selected to have 6 or more carbon atoms so that their reaction products with water have a low vapor pressure at temperatures less than 50° C.

The reactive salt can be synthesized by reacting the corresponding Lewis acid organometallic complex [M(R¹)ₙ(R²)ₘ]⁰ with the a salt of X, e.g., (A^{+b})_{c}X. Methods for synthesizing the Lewis acid organometallic desiccant of this invention can be found in Salt Effects in Organic and Organometallic Chemistry, VCH Publishers, Inc, New York, 1992.

Another useful set of desiccant materials includes those defined by Formula V

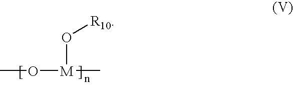

In Formula V, R₁₀ is one selected from the group including alkyl group, alkenyl group, aryl group, cycloalkyl group, heterocyclic group and acyl group having at least one carbon atom, M is a trivalent metal atom, and n is an integer of two to four.

Another useful set of desiccant materials includes those defined by Formula VI

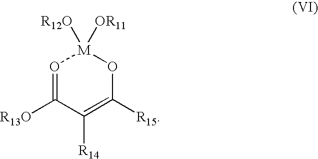

In Formula VI, each of R₁₁, R₁₂, R₁₃, R₁₄ and R₁₅ is one selected from the group including alkyl group, alkenyl group, aryl group, cycloalkyl group, heterocyclic group and acyl group having at least one carbon atom, and M is a trivalent metal atom.

Another useful set of desiccant materials includes those defined by Formula VII

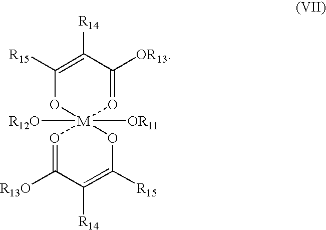

In Formula VI, each of R₁₁, R₁₂, R₁₃, R₁₄ and R₁₅ is one selected from the group including alkyl group, alkenyl group, aryl group, cycloalkyl group, heterocyclic group and acyl group having at least one carbon atom, and M is a tetravalent metal atom.

Although the materials defined in Formulas V-VII form alcohols when they react with water, they can be useful in this invention if proper precautions are taken. For example, a barrier layer between the desiccant and the OLED can be useful to stop diffusion of the alcohol. The R groups can be selected so that they are large enough to prevent any significant diffusion. Also, they might be part of a polymeric backbone that cannot diffuse. In addition, not all electronic devices are as sensitive to alcohols as an OLED device.

The desiccating film host can be any number of inert materials that serves to dilute the desiccant material in order to reduce aggregation and particle formation that would normally occur for the pure desiccant material. The host can be organic or inorganic, but preferably is organic.

The desiccant can be provided on the polymeric support 302 in numerous ways, depending on the material. They can be deposited by thermal vapor deposition to form a film of the desiccant. The film thickness is not limited, but it is believed that a thickness range of from 0.05 microns to 500 microns is suitable, depending on the application and the required of water absorption capacity. In the case of a molecularly dispersed desiccant, the desiccant and the host can be codeposited by thermal vapor deposition.

In some cases, the desiccant material(s), including the option of using a molecularly dispersed desiccant within a host, can be dissolved or suspended in an organic solvent such as acetates, ketones, cyclohexanes and provided over the polymeric support, for example, by spin coating, dip coating, curtain coating, ink jet deposition, and the like. When particulate desiccant materials are used, they can be coated along with a polymer binder. In the case of molecularly dispersed desiccants or particulate desiccants, the desiccating film host or binder can comprise inert polymeric matrix, for example poly(butyl methacrylate), which can be cast from an organic solvent such acetates, ketones, or cyclohexanes or mixtures thereof. A typical loading of desiccant relative to the polymer host is 0.05 to 50% by weight. Other polymers that can be used as a desiccating film host include, but are not limited to, polymethacrylates, polysiloxanes, poly vinylacetate, polystyrenes, polyacrylates, polybutadiene, or cycoloefine polymers. When the desiccating film host is a polymer or oligomer, the desiccant material can be covalently or ionically bound to the host so long as the desiccant moieties are molecularly dispersed relative to each other. The desiccant can be part of a pendant group or incorporated into the backbone of the host polymer.

The desiccant can also be molecularly dispersed into a polymer host without the presence of solvent by heating the polymer to reduce its viscosity, and mixing in the desiccant.

Flexible Support/Barrier/Desiccant/Barrier

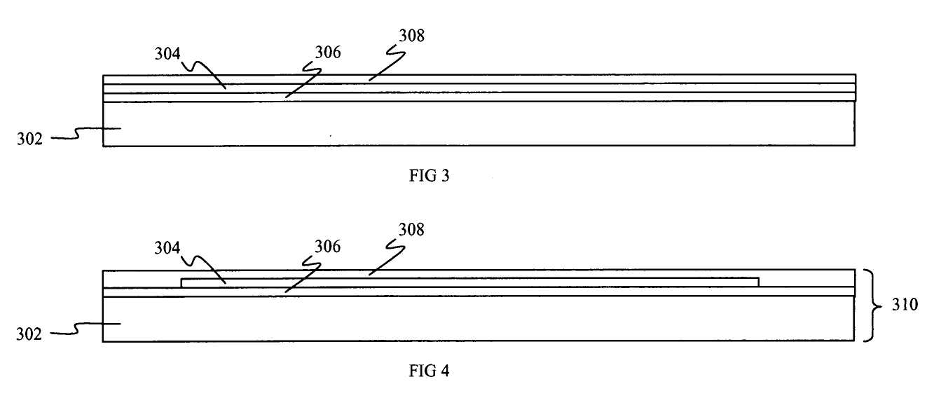

It is particularly advantageous to use the desiccant in combination with barrier layers. It will be understood that multiple desiccant layers can be used interspersed between barrier layers. A barrier layer can be provided between the polymeric support and the desiccant, over the desiccant, or both. All of these layers provide a flexible substrate. Turning now to FIG. 3, a first barrier layer 306 is provided over the polymeric support 302. Desiccant layer 304 is provided over the first barrier layer 306, and a second barrier layer 308 is provided over the desiccant layer 304 and first barrier layer 306. As described previously, the first and second barrier layers can each be a single layer or a plurality of sublayers, for example, alternating inorganic/organic sublayers.

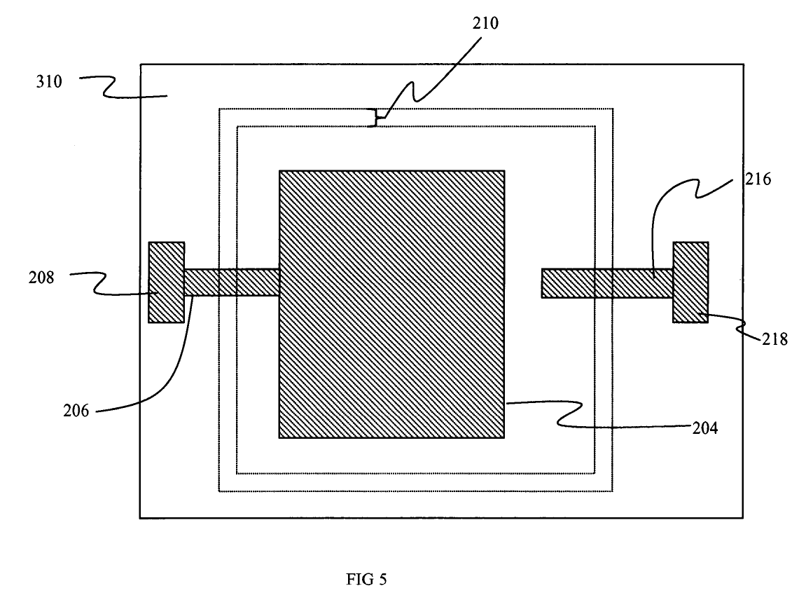

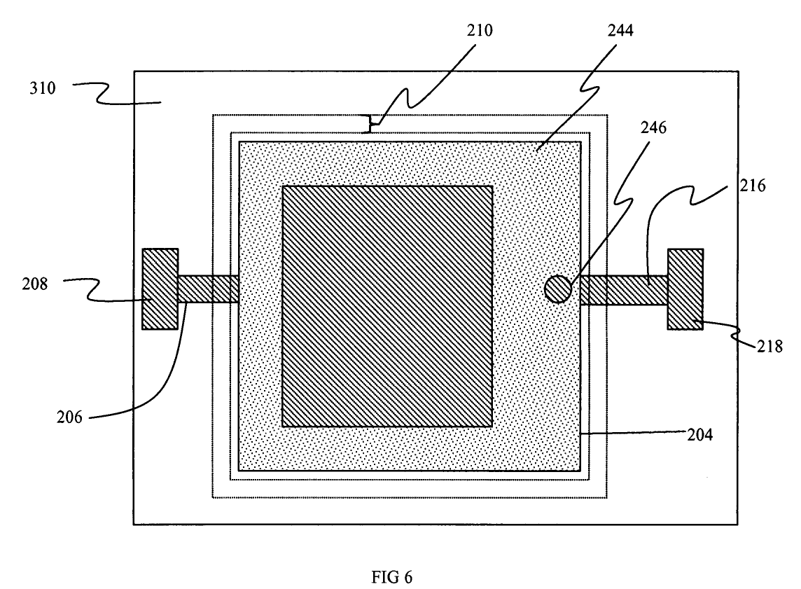

In another embodiment of a flexible substrate, FIG. 4 shows a first barrier layer 306 provided over the polymeric support 302. Desiccant layer 304 is patterned over the first barrier layer 306 and a second barrier layer 308 is provided over the desiccant layer 304 and over the first barrier layer 306. Desiccant layer 304 has a smaller area than the first or second barrier layers, 306 and 308 respectively. Polymeric support 302, first barrier layer 306, desiccant layer 304, and second barrier layer 308 are collectively referred to as polymeric substrate 310. The advantage of this embodiment is that there is less chance of delamination of the second barrier layer that can be caused by high levels of moisture reacting with the desiccant near the edges of the support. In many device embodiments, the edges of the flexible support are exposed to ambient. Even if no delamination occurs, the desiccant layer 304 can be quickly consumed if the edges are directly exposed to the ambient. In FIG. 4, the desiccant layer 304 is encased between two barrier layers. Although the desiccant can rapidly capture moisture that can penetrate through minor defects in either barrier layer, it will not be consumed quickly because there is no edge moisture path available from the ambient.

OLED Device Fabrication

FIGS. 5-7 illustrate various stages of the fabrication of an OLED device 200A. Turning first to FIG. 5, a top view of an OLED polymeric substrate 310 is shown. A predetermined seal area 210 is represented by the space between the dotted lines in FIG. 2. The inner dotted line further represents the sealed region of the OLED device. Over OLED polymeric substrate 310 are provided a first electrode 204, a first electrical contact pad 208, and a first electrical interconnect line 206 that provides an electrical connection between the first electrode 204 and the first electrical contact pad 208. The first electrical interconnect line 206 extends through the seal area. As discussed previously, the first electrode 204 can be the anode or cathode, and can be any number of well known conductive materials, as discussed above. The conductive material used for each of the first electrode 204, the first electrical interconnect line 206, and the first electrical contact pad 208 can be the same or different. In addition, each of the first electrode 204, the first electrical interconnect line 206, and the first electrical contact pad 208 can contain two or more layers of different conductive materials.

A second interconnect line 216 and a second contact pad 218 are provided over the OLED polymeric substrate 310 to provide a way for making electrical contact to a second electrode that is formed in a later step. The conductive material used for the second contact pad 218 and second interconnect line 216 can be the same or different, and can also be the same or different from the material(s) used as the first electrical contact pad 208 and first electrical interconnect line 206.

The conductive materials for forming the first electrode 204, the first and second interconnect lines, and the first and second contact pads can be deposited by vacuum methods such as thermal physical vapor deposition, sputter deposition, plasma-enhanced chemical vapor deposition, electron-beam assisted vapor deposition, and other methods known in the art. In addition, so-called “wet” chemical processes can be used such as electroless and electrolytic plating. The first electrode 204, the first electrical interconnect line 206, the first electrical contact pad 208, the second interconnect line 216 and the second contact pad 218 can be provided in the same patterning step or different patterning steps. Patterning can be achieved by deposition through a shadow mask, photolithographic methods, laser ablation, selective electroless plating, electrochemical etching, and other well known patterning techniques.

The second first electrode 204, interconnect lines 206 and 216, and contact pads 208 and 218 are made from aluminum. Although the first electrode can be transparent, in this arrangement, the first electrode functions as the anode and is reflective and opaque. In order to provide a high work function surface for effective hole injection, a layer of indium-doped tin oxide (ITO) is provided over the anode (not shown). The second contact pad 218 and second interconnect line 216 are made from aluminum in this embodiment.

Turning now to FIG. 6, an insulation layer 244 is provided in a pattern over the OLED polymeric substrate 310. The insulation layer 244 extends over a portion of the first electrode 204 and over at least a portion of the first and second interconnects, 206 and 216. A via 246 is provided over the second interconnect line 216 that is located inside the sealed region. The insulation layer 244 does not extend through the predetermined seal area 210 in this embodiment.

The insulation layer 244 can be any number of organic or inorganic materials provided that the material has low electrical conductivity and provides effective adhesion with the surfaces over which it is applied. The insulation layer 244 acts to reduce shorting that can occur between first and second electrodes, and can provide planarization. Insulation layer 244 is typically provided in a thickness of from a few nanometers to a few microns. Many of the same materials and deposition methods can be used to form the insulation layer 244 as described above for barrier layer materials.

Some examples of organic materials that are useful for the insulation layer 244 include polyimides, parylene, and acrylate-based photoresist materials. Some examples of inorganic materials that are useful for the insulation layer 244 include metal oxides such as silicon oxides and aluminum oxides, and metal nitrides such as silicon nitride and ceramic composites. In addition, the materials can be provided from a solution, such as a sol-gel.

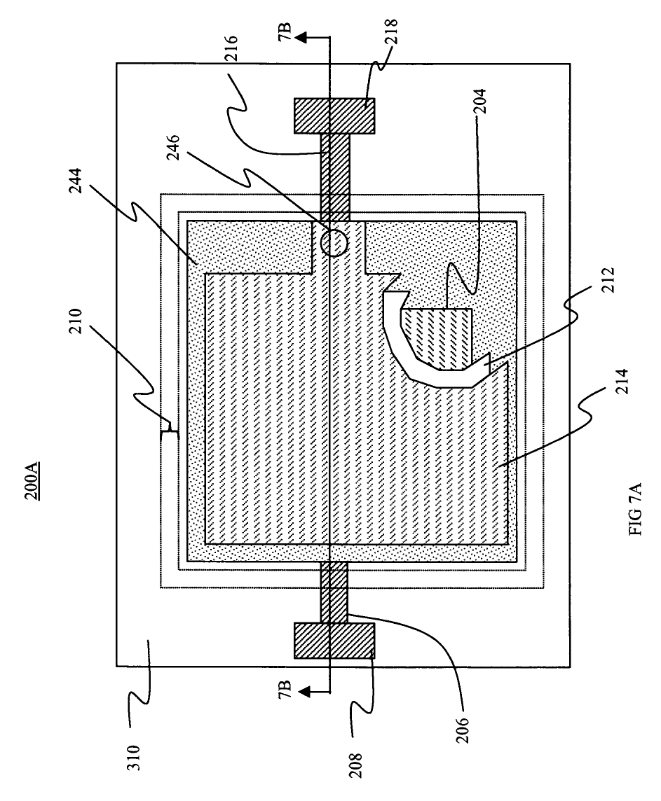

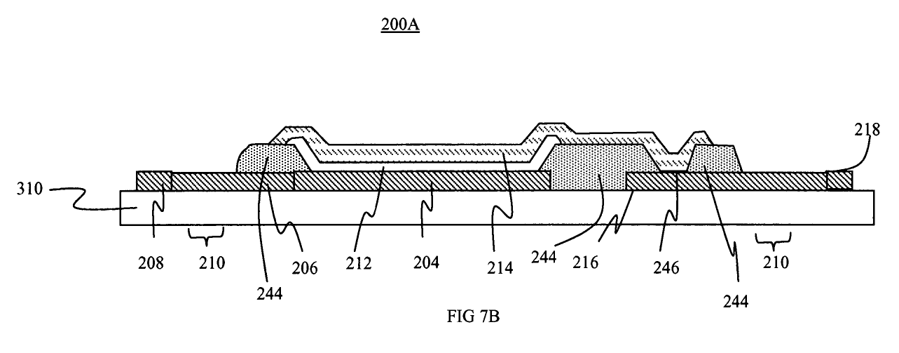

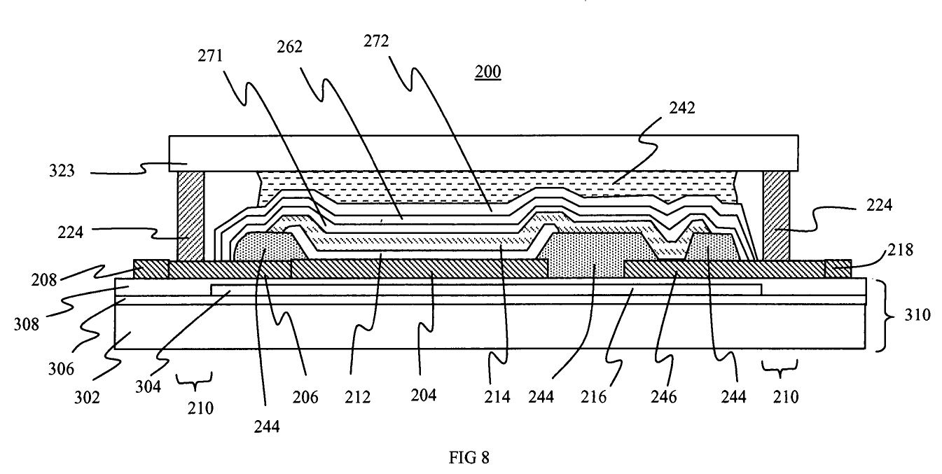

As shown in FIG. 7A, the organic EL media layer 212 and second electrode 214 are then deposited to make OLED device 200A. To illustrate the layer order, the lower right corner of first electrode area is pictorially cut away to show the first electrode 204. A cross-sectional view taken along lines 7B-B is shown in FIG. 7B. Note that the detailed layer structure of polymeric substrate 310 is not shown. In this arrangement, the second electrode is the cathode and is semitransparent. It is made from a thin layer of Li (e.g., 1 nm) in contact with the organic EL media, a thin layer of Al (e.g., 10 nm) over the lithium, and a thicker layer of ITO (e.g. 100 nm) over the Al. The cathode makes contact to the second interconnect line 216 in the via.

To illustrate the layer order, the lower right corner of first electrode area is pictorially cut away to show the first electrode 204. The organic EL media layer 212 is described in more detail below, but it can contain one or several layers of different materials. The organic EL media layer 212 is provided over the entire first electrode 204 and over a portion of the insulation layer 244. The organic EL media layer does not extend into the via 246 or through the predetermined seal area 210. The second electrode 214 is patterned over the first electrode and into the via 246, but does not contact the first electrical interconnect line 206. The light-emitting area (pixel) is defined by the area of overlap of the first electrode 204 with the second electrode 214, wherein there is organic EL media sandwiched there between. Because the first electrode is reflective and opaque, and the second electrode is semitransparent, this light will emit in a direction away from polymeric substrate 310. This is referred to as a “top-emitting” OLED. The present invention can also work with a bottom emitting OLED where light is transmitted through the substrate so long as the layers of polymeric substrate 310 are transmissive to light.

The second electrode 214 can be deposited and patterned using methods previously described.

Turning now to FIG. 8, a top-emitting, encapsulated OLED device 200 is shown. In this arrangement, an optional first barrier layer 271 is provided over the OLED device. As described previously, the barrier layer can be a single layer or a plurality of sublayers, for example, alternating inorganic/organic sublayers. An optional light transmissive desiccating film 262 is provided over first barrier layer 271. In addition to producing an additional barrier to moisture penetration, first barrier layer 271 can protect the OLED from solvents or chemical reactions associated with the light transmissive desiccating film. An optional second barrier layer 272 has been provided over light transmissive desiccating film 262. Over the second barrier layer 272, an optional polymer buffer layer 242 provided.

When light is taken out through the cover, the polymer buffer layer is selected to be transparent or nearly transparent, and having this layer between the cathode and the cover can improve optical out-coupling. The polymer buffer layer 242 can be any number of materials including UV or heat cured epoxy resin, acrylates, or pressure sensitive adhesive. An example of a useful UV-curable epoxy resin is Optocast 3505 from Electronic Materials Inc. An example of useful pressure sensitive adhesive is Optically Clear Laminating Adhesive 8142 from 3M. The polymer buffer layer 242 can also serve a dual role as the light transmissive desiccating film.

An optional cover 323 is provided having deposited thereon a seal material 224 in a pattern corresponding to the predetermined seal area 210. It is useful in many instances that the cover 323 be flexible. The polymer buffer layer 242 does not have to be deposited onto the OLED device, but can be provided on the cover 323 along with seal material 224. Alternatively, the polymer buffer layer material can also serve as the seal material. The cover 323 with the patterned seal material 224 is provided over the OLED device 200A in alignment with the predetermined seal area 210. Pressure is applied between the polymeric support 302 and the cover 323 while the seal material is cured or fused. The sealing step is preferably done under inert conditions such as under vacuum or under a dry nitrogen or argon atmosphere. The cover can be made from glass, metal, a ceramic, a polymer or a composite. In this arrangement, it should be light transmissive, but it does not have to be such if light is transmitted through the first electrode. Preferably, if a polymer cover is used, it is provided with a moisture barrier layer(s) adjacent to the interface with the seal material.

The seal material 224 can be an organic adhesive such as UV or heat cured epoxy resin, acrylates, or pressure sensitive adhesive. Alternatively, the seal material can be a glass frit seal material or a metal solder. However, because such materials typically require high temperatures for sealing, organic seal materials are preferred.

The first barrier layer 306 can be conductive (e.g., aluminum), so long as the second barrier layer 308 is not. This is to prevent shorting between the first and second electrodes. A bottom-emitting structure can also be made so long as the polymeric substrate 310 is substantially transparent to light.

Polymeric Support with Patterned Desiccant

As shown in FIG. 8, the area of desiccant 306 is sized to accommodate the particular device for which it is intended. However, in some manufacturing settings it is desirable that the flexible substrate has more versatility. That is, it is advantageous to use the same flexible substrate for multiple purposes or differently sized devices, and avoid the potential problems of ambient moisture at the edges of the flexible substrate.

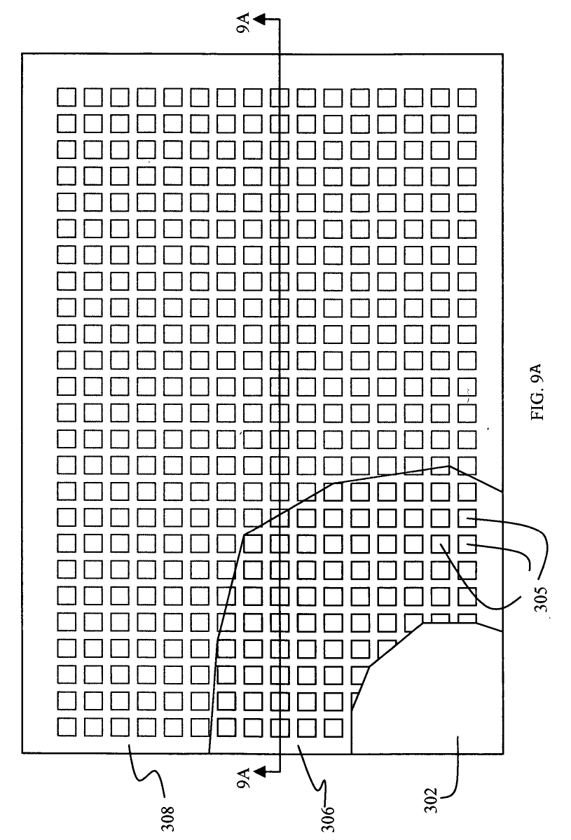

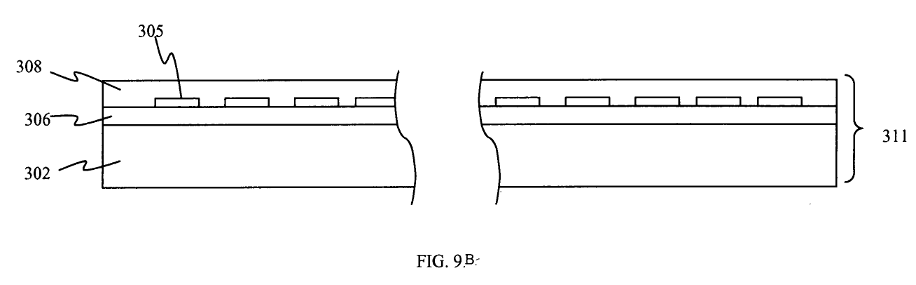

Turning to FIG. 9A, a plan view of a polymeric support 302 over which patterned desiccant layer 305 has been provided in a discontinuous pattern of island-like regions. The lower left corner has been cut away to show more clearly the layer structure. As in FIG. 4, the patterned desiccant layer 305 is provided between first and second barrier layers 306 and 308. A cross-sectional view is shown in FIG. 9B taken along lines 9A-A. The assembly is polymeric substrate 311. The discontinuous desiccant reduces the potential for delamination of the second barrier layer 308 and avoids the rapid consumption of desiccant associated with moisture penetration from the edges. These advantages are maintained regardless of how the polymeric substrate 311 is cut.

Patterning of the desiccant in island-like regions can be done by shadow masking if the desiccant is vapor deposited. For solution applied desiccant, patterning methods include, but are not limited to, contact printing, screen printing, ink jet, and photolithography. Thermal transfer from a donor element can be used. Patterned surface modification of the substrate to affect wetting and/or adhesion properties of the desiccant to the substrate can be used. Physical surface features in the substrate, e.g., patterned wells, can be used to produce sites where the desiccant will deposit.

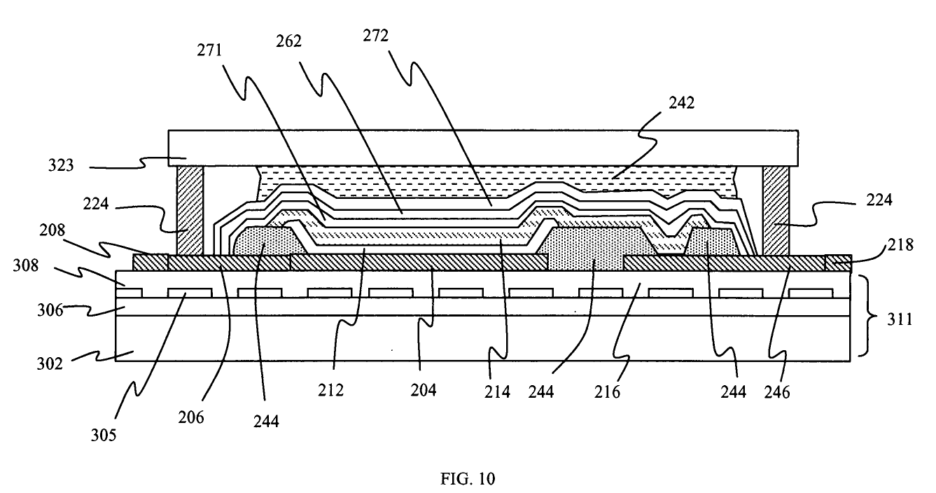

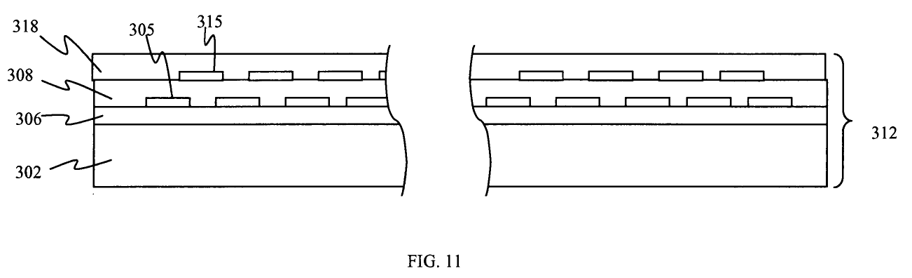

Turning now to FIG. 10, an OLED display is shown using the substrate from FIG. 9B. It is fabricated in a manner entirely analogous to that shown in FIG. 8 except that polymeric substrate 310 has been replaced with polymeric substrate 311. Patterned desiccant layer 305 provides an excellent moisture trap for water vapor that permeates the flexible support 302 and defects in first barrier layer 306. Light transmissive desiccating film 262 provides an excellent moisture trap for water vapor that can be trapped in the sealed area or that permeates the seal material 224.

Turning to FIG. 11, a cross-sectional view of another embodiment of this invention. Polymeric substrate 312 is analogous to polymeric substrate 311 from FIG. 9B, except that an additional layer of patterned desiccant layer 315 and third barrier layer 318 are provided. The materials used for these features can be the same as or different from the materials used for patterned desiccant layer 305 and second barrier layer 308. The location of patterned desiccant layer 315 is staggered relative to the patterned desiccant layer 305 in order to provide additional protection to the electronic device that is formed over polymeric substrate 312.

The invention has been described in detail with particular reference to certain preferred embodiments thereof, but it will be understood that variations and modifications can be effected within the spirit and scope of the invention.

### PARTS LIST

101 substrate
103 anode
105 hole-injecting layer
107 hole-transporting layer
109 light-emitting layer
111 electron-transporting layer
113 cathode
150 voltage/current source
160 electrical conductors
200 encapsulated OLED device
200A OLED device
204 first electrode
206 first electrical interconnect line
208 first electrical contact pad
210 seal area
212 organic EL media layer
214 second electrode
216 second interconnect line
218 second contact pad
224 seal material
242 polymer buffer layer
244 insulation layer
246 via
262 light transmissive desiccating film
271 first barrier layer
272 second barrier layer
302 polymeric support
304 desiccant layer
304B desiccant layer
304C desiccant layer
305 patterned desiccant layer
306 first barrier layer
308 second barrier layer
310 polymeric substrate
311 polymeric substrate
312 polymeric substrate
315 patterned desiccant layer
318 third barrier layer
323 cover

1. A polymeric substrate for a moisture-sensitive electronic device comprising:
a) a polymeric support having a top and bottom surface; and
b) a desiccant layer disposed over at least a portion of the top or bottom surface of the polymeric support, or both.

2. The polymeric substrate of claim 1 further including an inorganic barrier layer disposed over the desiccating layer or between the desiccating layer and the polymeric support.

3. The polymeric substrate of claim 1 wherein the desiccant layer is further provided over at least a portion of side surfaces of the polymeric support.

4. The polymeric substrate of claim 2 wherein the desiccant layer is further provided over at least a portion of side surfaces of the polymeric support.

5. A polymeric substrate for a moisture-sensitive electronic device comprising:
a) a polymeric support having a top and bottom surface; and
b) a host and a desiccant molecularly dispersed in such host defining a desiccating film that is disposed over at least a portion of the top or bottom surface of the polymeric support, or both.

6. The polymeric substrate of claim 5 further including an inorganic barrier layer disposed over the desiccating film or between the desiccating film and the polymeric support.

7. The polymeric substrate of claim 5 wherein the desiccating film is further provided over at least a portion of side surfaces of the polymeric support.

8. The polymeric substrate of claim 6 wherein the desiccating film is further provided over at least a portion of side surfaces of the polymeric support.

9. A polymeric substrate for a moisture-sensitive electronic device comprising:
a) a polymeric support having a top and bottom surface; and
b) a plurality of alternating layer structures formed over the top or bottom surfaces of the polymeric support, or both, wherein such alternating layer structure includes:
i) a desiccant layer; and
ii) an inorganic barrier layer provided over the desiccant layer.

10. A polymeric substrate for a moisture-sensitive electronic device comprising:
a) a polymeric support having a top and bottom surface; and
b) a plurality of alternating layer structures formed over the top or bottom surfaces of the polymeric support, or both, wherein such alternating layer structure includes:
i) a host and a desiccant molecularly dispersed in such host defining a desiccating film; and
ii) an inorganic barrier layer provided over the desiccating film.

11. A polymeric substrate for a moisture-sensitive electronic device comprising:
a) a polymeric support having a top and bottom surface; and
b) a patterned desiccant layer disposed over the top or bottom surface of the polymeric support, or both.

12. The polymeric substrate of claim 111 wherein the patterned desiccant layer is discontinuous.

13. The polymeric substrate of claim 11 wherein the desiccant layer is a desiccating film having a host and desiccant molecularly dispersed in such host.

14. The polymeric substrate of claim 12 wherein the desiccant layer is a desiccating film having a host and desiccant molecularly dispersed in such host.

15. The polymeric substrate of claim 11 further including an inorganic barrier layer disposed over the desiccant layer or between the desiccant layer and the polymeric support.

16. The polymeric substrate of claim 12 further including an inorganic barrier layer disposed over the desiccant layer or between the desiccant layer and the polymeric support.
